(19) United States
(12) Patent Application Publication
(10) Pub. No.: US 2025/0001450 A1
(43) Pub. Date: Jan. 2, 2025

(54) SUBSTRATE SUPPORT

(71) Applicant: SINGULUS TECHNOLOGIES AG, Kahl am Main (DE)

(72) Inventors: Stefan KEMPF, Alzenau (DE); Emmerich Manfred NOVAK, Kloster Lehnin (DE); Michael REISING, Mömbris (DE); Johannes RICHTER, Dieburg (DE)

(21) Appl. No.: 18/575,133

(22) PCT Filed: Apr. 7, 2022
(86) PCT No.: PCT/EP2022/059201

§ 371 Date: Dec. 28, 2023

(30) Foreign Application Priority Data
Jun. 28, 2021 (DE) 10 2021 003 330.2

(51) Int. Cl. B05C 13/00

(52) U.S. Cl. CPC B05C 13/00

(57) ABSTRACT

The present invention relates to a substrate carrier for receiving and transporting several substrates.

The present invention relates to a substrate carrier for receiving and transporting several substrates.

In a number of industrial processes, substrate carriers (or so-called “carriers”) for receiving and transporting a plurality of substrates are used to introduce the substrates into corresponding processing plants, carry them during substrate treatment and/or transport them between different units of such processing plants. Inter alia, such substrate carriers are utilized during the coating of substrates or wafers.

Examples of different substrate carriers may be found in US 2007/241454 A1, US 2005/214398 A1, US 2011/000882 A1, US 2012/0006489 A1 as well as CN 206685356 U.

Depending on the type of industrial process in which these substrate carriers come into use, different requirements are made to these substrate carriers. In this context, with regard to, e.g., two-sided coating processes, it is important that the substrates are stored in their “nests” in a securely centered manner with respect to the respective coating openings, wherein edge coverage resulting from the storage should be minimized at the same time. Furthermore, it should be possible to insert and remove the substrates in a simple manner without damaging the substrates. Furthermore, different processes may lead to strong variations in temperature since the substrates are subjected to, e.g., different heating and cooling steps within the course of a coating process. In doing so, the substrate carriers may be deformed, which may lead to substrates resting in the nest in an undefined manner and, as a result, to flawed coating.

It is an object of the present invention to provide improved substrate carriers against the background of the requirements discussed above.

The present invention relates to a substrate carrier for receiving and transporting several substrates, wherein the substrate carrier comprises a frame with two opposing running rails and at least two further elongate frame members as well as one or more supporting plates mounted to the frame. The running rails of the substrate carrier frame serve for transportation of the substrate carrier in a corresponding transportation device, which may engage with the running rails. The two running rails of the substrate carrier frame extend along a first direction which corresponds to the moving direction during transportation in a corresponding process during use of the substrate carrier. The at least two elongate frame members extend along a second direction perpendicular to the first direction. The supporting plates serve for receiving several substrates and define a first plane (with the first and second directions being generally parallel to said first plane). Each of the one or more supporting plates comprises several receiving openings for receiving one substrate each (which form the aforementioned “nests”). In each case, a supporting plate web is formed between receiving openings adjacent to each other in the first direction, said supporting plate web extending along the second direction. Each of the supporting plates further comprises at least two elongate openings, preferably slots, each extending substantially perpendicular to the plane through the supporting plate and substantially along the first direction so that a connecting member is formed between each two openings of the at least two openings adjacent to each other in the first direction. In this context, there is an offset along the first direction between the supporting plate webs extending along the second direction and the connecting member.

The invention is, inter alia, based on the idea of using the at least two elongate openings extending along the first direction to compensate for different thermal expansions of the supporting plate and the frame member during process-related temperature fluctuations. Since the supporting plate usually heats up more than the frame members during, e.g., a coating process, it will expand more along the second direction than the corresponding elongate frame members. This expansion may then occur into the region of the elongate openings, which thus compensate for said expansion without causing distortions within the supporting plate.

In this context, the specific shape of the elongate openings is eventually irrelevant if enough clearance is provided for the expansion of the supporting plate material. It is also not critical that the elongate openings extend exactly along the first direction. Rather, they can also assume an angle of, e.g., 5° and up to 10° with the first direction. The elongate openings do not have to extend exactly perpendicular to the plane through the supporting plate, either. It is only important that they are through-holes so that the supporting plate may expand over its entire thickness. However, the elongate openings could also be inclined with respect to the vertical to the first plane and, e.g., assume an angle with the vertical of up to 10°. However, the elongate openings should preferably be optically tight so that, e.g., no coating material can pass through said elongate openings during a coating process.

As a matter of course, these elongate openings cannot extend along the complete length of the supporting surface since they would otherwise not be connected with the running rails anymore. Thus, a connecting member connecting the supporting plate with the running rail beyond the openings is required between each two openings of the at least two openings that are adjacent to each other in the first direction. Since the aforementioned possibility of expansion of the supporting plate material in the region of the connecting member is not guaranteed, according to the invention there is an offset along the first direction between the supporting plate webs extending along the second direction and the connecting member. This is to make sure that the connecting member is located just where there is hardly any supporting plate material due to the receiving openings, whereas an elongate opening is provided where the supporting plate webs are located and thus where there is a lot of expanding material.

Preferably, there should be a certain minimum offset. If the receiving openings have a width along the first direction, the offset is preferably at least 20%, more preferably at least 30%, and particularly preferably at least 40% of said width of the receiving openings. Ideally, the connecting member should be arranged centrally with respect to the width of the receiving opening.

The connecting members should be dimensioned in such a way that, on the one hand, they ensure sufficient stability of the supporting plate and, on the other hand, they do not impair the expansion of the supporting plate material. Against this background, it is preferred that the connecting member has a width along the first direction of at least 10 mm, preferably at least 12 mm, and particularly preferably at least 14 mm. It is further preferred that the connecting member has a width along the first direction of at most 20 mm, more preferably at most 18 mm, and particularly preferably at most 16 mm.

In order to provide sufficient space for the expansion of the supporting plate material, it is preferred that each of the elongate openings has a width along the second direction of at least 0.5 mm, more preferably at least 0.7 mm, and particularly preferably at least 0.9 mm. Furthermore, each of the elongate openings has a width along the second direction of preferably at most 5 mm, more preferably at most 3 mm, and particularly preferably at most 1.5 mm.

Preferably, the distance along the second direction between each of the elongate openings and the receiving openings adjacent to each other in the second direction is at least 10 mm, more preferably at least 12 mm, and particularly preferably at least 14 mm.

The supporting plate webs have a width, and the distance along the second direction between each of the elongate openings and the receiving openings adjacent to each other in the second direction is preferably at least 70%, more preferably at least 80%, and particularly preferably at least 90% of the width of the supporting plate webs.

Preferably, the elongate openings form an angle with the vertical to the first plane that is between 0° and 10°, more preferably between 2° and 8°.

It is further preferred that the elongate openings on one side each extend to the edge of the supporting plate. If three or more openings per supporting plate are provided, this obviously only applies to the openings on the edge side.

The supporting plates are connected, preferably permanently, to the running rails, e.g., bolted together. Furthermore, the supporting plates are connected, preferably movably, to the elongate frame members. To this end, each of the elongate frame members comprises several receiving openings for receiving corresponding connecting members of the supporting plates. Preferably, the receiving openings allow for clearance of the connecting members of the supporting plates along the second direction in order to tolerate expansion of the supporting plates along the second direction. The receiving openings comprise a first extension along the second direction, and the connecting members of the supporting plate comprise a second extension along the second direction, wherein the ratio between the second and first extension is preferably smaller than 0.95, more preferably smaller than 0.9, and particularly preferably smaller than 0.85. Preferably, at least one of the elongate openings extends through one of the connecting members.

In the following, preferred embodiments of the present invention are described in more detail with respect to the Figures, wherein

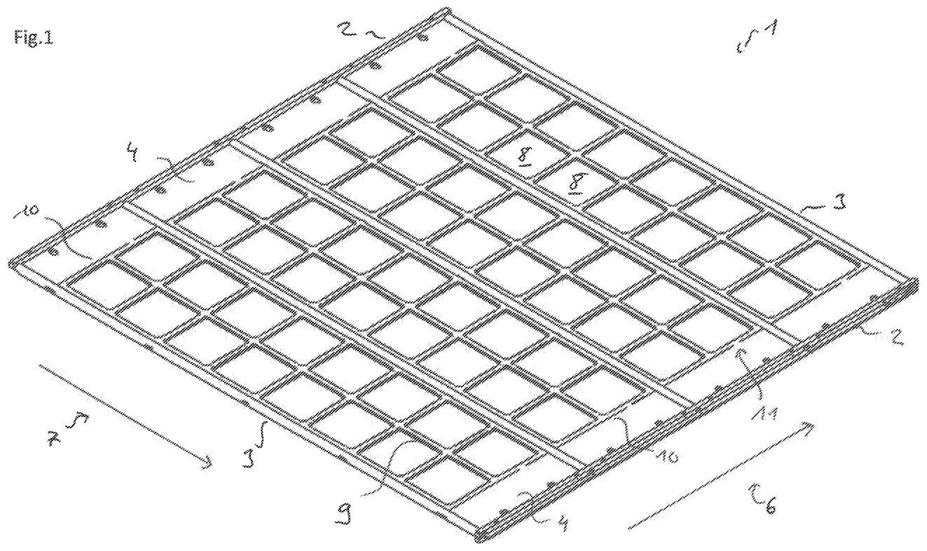

FIG. 1 shows a perspective view of a substrate carrier according to a preferred embodiment of the present invention;

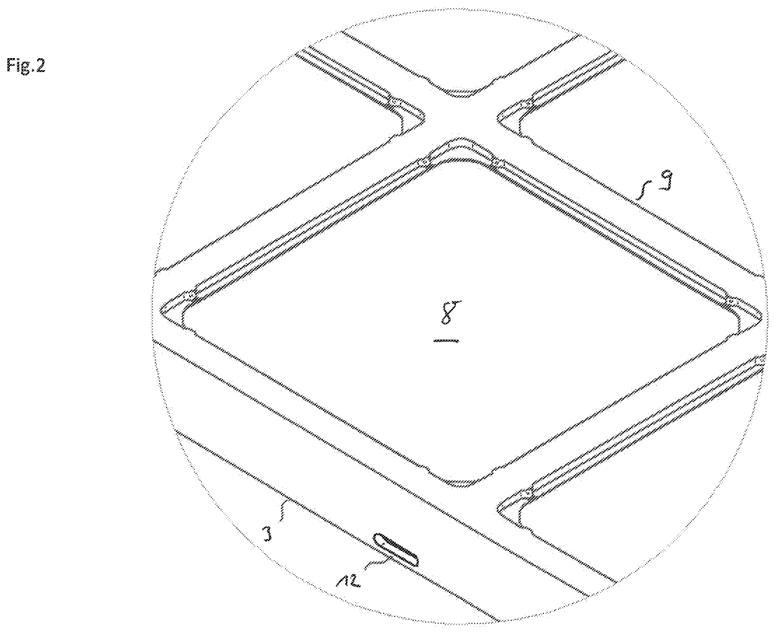

FIG. 2 shows a “nest” for a substrate in a substrate carrier according to FIG. 1; and

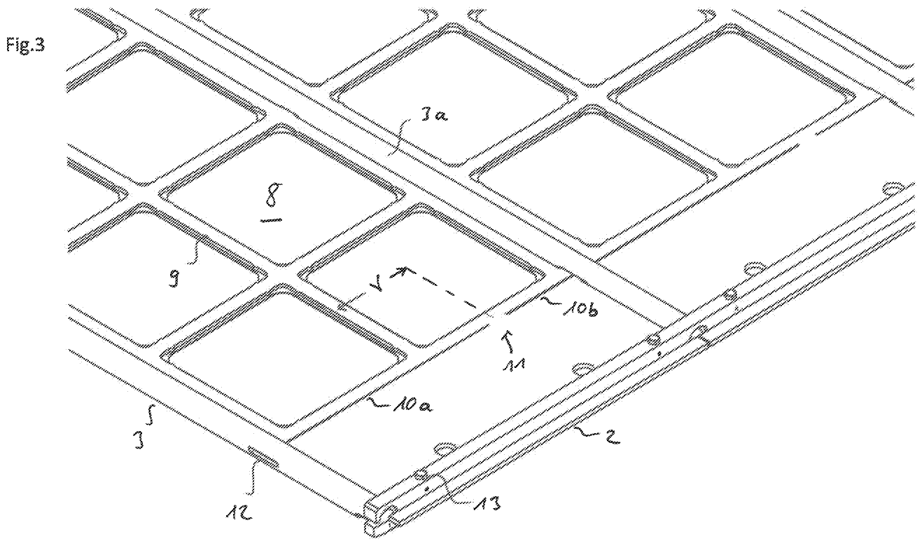

FIG. 3 shows a perspective, detailed view of the substrate carrier according to FIG. 1.

FIG. 1 shows a perspective view of a substrate carrier 1 according to a preferred embodiment of the present invention.

The substrate carrier 1 serves for receiving and transporting several substrates which may be received in corresponding receiving openings 8. In the illustrated exemplary embodiment, there are 64 of such receiving openings 8. As a matter of course, however, more or fewer receiving openings may also be provided in a square, rectangular, or other arrangement. The substrate carrier 1 comprises a frame with two opposing running rails 2 and two further opposing elongate frame members 3. Moreover, four supporting plates 4 are provided, which are mounted to the frame. Further elongate frame members 3a (cf. FIG. 3) are provided in each case between two adjacent supporting plates 4 so that in the preferred embodiment shown, each supporting plate is framed and held by the two opposing running rails 2 on the one hand and two further elongate frame members 3, 3a on the other hand. As a matter of fact, fewer or more supporting plates may be provided in this case as well. If there is only one supporting plate, the center frame members 3a can be omitted.

The two running rails 2, which can be seen particularly well in FIG. 3, serve for transportation of the substrate carrier 1 in a corresponding transportation device and are designed and configured such that they may engage with corresponding members of the transportation device. The supporting plates 4 are each permanently connected to the two running rails 2. In the illustrated embodiment, the connection is made by means of bolts 13 (cf. FIG. 3).

The two running rails 2 extend along a first direction, which is indicated in FIG. 1 by arrow 6. The two or more further elongate frame members 3 and 3a extend along a second direction that is perpendicular to the first direction 6 and indicated in FIG. 1 by arrow 7. Further, the supporting plates define a first plane which may be characterized by the surface of the supporting plates or by the surface in which the substrates are held.

In the case of the preferred embodiment illustrated here, each of the four supporting plates 4 comprises 16 receiving openings 8 for receiving one substrate each (i.e., for receiving 16 substrates in total) so that a supporting plate web 9 is formed in each case between two receiving openings 8 adjacent to each other in the first direction 6, which web extends along the second direction 7. Due to the symmetric arrangement of the receiving openings 8, the individual supporting plate webs 9 form a continuous web which substantially extends over the complete width of the substrate carrier 1, wherein one such web is provided per supporting plate 4. As a matter of course, if the receiving openings 8 were arranged differently in the supporting plate 4, two or more webs would be formed in three or more rows accordingly. Incidentally, corresponding supporting plate webs are also formed in each case between two receiving openings 8 adjacent to each other in the second direction 7, but these are not important for the following discussion.

With respect to the stability of the frame of the substrate carrier, the elongate frame members 3, 3a are configured to be more massive than the supporting plate webs 9. For instance, the elongate frame members 3 and 3a may be tubular elements, as can be taken from, e.g., FIG. 2. The frame members may also be made of a different material than the supporting plates. So if the substrate carrier is heated together with the substrates placed thereon, e.g., during a coating process, the supporting plate webs 9 will heat up faster than the massive frame members 3, 3a so that the supporting plate webs 9 will expand more strongly than the corresponding frame members 3, 3a. As will be readily apparent, this can lead to corresponding distortions within the supporting plates 4, which then results in the substrates no longer being precisely supported in the well-defined first plane, making it possible for defects to occur during coating. According to the invention, at least two elongate openings 10 are provided in each supporting plate 4, respectively, in order to compensate for said expansion, which openings, in the case of the preferred embodiment shown here, are provided in the form of two elongate slots 10a and 10b (cf. FIG. 3). in the illustrated embodiment, these two slots 10a and 10b extend perpendicularly to the first plane, which is defined by the supporting plate 4, through the supporting plate and along the first direction 6. However, as is readily apparent from FIG. 3, the slots 1a and 10b could also extend transversely through the material of the supporting plate 4 so as to assume an angle with the vertical to the first plane and/or extend with an inclination with respect to the first direction 6.

The only decisive factor is that where the supporting plate webs 9 form a continuous strand of material along the second direction 7, a clearance is created into which the expansion of the material can take place. To this end, an offset V (cf. FIG. 3) is provided between the connecting member 11, which is formed in each case between two openings or slots 10a and 10b adjacent to each other in the first direction 6, and the supporting plate webs extending along the second direction 7. As is readily apparent, the connecting member 11 is preferably centered with respect to the width of the receiving opening 8, as illustrated in FIG. 3. However, this is not necessary as long as the offset V is sufficiently large to allow the web material to escape into the slot opening. If the offset is defined as the distance between the respective centers of the supporting plate web 9 as well as the connecting member 11, the offset should be at least half the sum of the widths of the supporting plate web and the connecting member. Preferably, however, the offset is at least 20% of the width of the receiving openings 8 along the first direction 6.

In the preferred embodiment shown, two slots 10a and 10b (cf. FIG. 3) are provided on each side of each supporting plate 4, respectively (cf. FIG. 1). However, the slots could be provided on one side only and/or there could be more than two slots per side. In particular, for each row of receiving openings 8 there can be one connecting member 11 between adjacent slots 10, so that in the embodiment shown, three slots with two connecting members could also be useful. However, it is preferred that the edge slots on one side each extend to the edge of the supporting plate 4, as can be seen in FIG. 3.

The elongate frame members 3 and 3a may each have several receiving openings 12 for receiving corresponding connecting members of the supporting plates 4. In the preferred exemplary embodiment shown here, the tubes 3 each comprise several elongate slots 12 for receiving corresponding projections of the supporting plates 4, as can be seen in FIGS. 2 and 3. It is preferred that the receiving openings 12 allow for clearance of the connecting members of the supporting plate 4 along the second direction 7 in order to compensate for different thermal expansion in this way as well. It is further preferred that at least one of the elongate openings of slots 10a and 10b extends through one of the connecting members, as is shown in FIG. 3.

1. A substrate carrier for receiving and transporting several substrates, wherein the substrate carrier comprises a frame with two opposing running rails and two further elongate frame members and one or more supporting plates which are connected to the frame, wherein the two running rails extend along a first direction, the two elongate frame members extend along a second direction perpendicular to the first direction, and the supporting plates define a first plane, wherein each of the one or more supporting plates comprise several receiving openings for receiving one substrate each so that a supporting plate web is formed between two respective receiving openings adjacent to each other in the first direction, said supporting plate web extending along the second direction, wherein each of the supporting plates comprises at least two elongate openings extending substantially perpendicular to the first plane through the supporting plate and substantially along the first direction so that a connecting member is formed between two respective openings adjacent to each other in the first direction, and wherein there is an offset along the first direction between the supporting plate webs extending along the second direction and the connecting member.

2. The substrate carrier according to claim 1, wherein the receiving openings have a width along the first direction and wherein the offset is at least 20% of the width.

3. The substrate carrier according to claim 2, wherein the connecting member is disposed centrally with respect to the width of the receiving opening.

4. The substrate carrier according to claim 1, wherein the connecting member has a width along the first direction of at least 10 mm.

5. The substrate carrier according to claim 1, wherein the connecting member has a width along the first direction of at least 20 mm.

6. The substrate carrier according to claim 1, wherein each of the elongate openings has a width along the second direction of at most 0.5 mm.

7. The substrate carrier according to claim 1, wherein each of the elongate openings has a width along the second direction of at most 5 mm.

8. The substrate carrier according to claim 1, preceding claims, wherein the distance along the second direction between each of the elongate openings and the receiving openings adjacent to each other in the second direction is at least 10 mm.

9. The substrate carrier according to claim 1, preceding claims, wherein the supporting plate webs have a width and wherein the distance along the second direction between each of the elongate openings and the receiving openings adjacent to each other in the second direction is at least 70% of the width of the supporting plate webs.

10. The substrate carrier according to claim 1, wherein the elongate openings form an angle of between 0° and 10° with the vertical to the first plane.

11. The substrate carrier according to claim 1, wherein the elongate openings on one side thereof each extend to the edge of the supporting plate.

12. The substrate carrier according to claim 1, wherein each of the elongate frame members comprises several receiving openings for receiving corresponding connecting members of the supporting plates.

13. The substrate carrier according to claim 12, wherein the receiving openings for receiving the connecting members allow for clearance of the connecting members of the supporting plate along the second direction.

14. The substrate carrier according to claim 12, wherein the receiving openings for receiving the connecting members comprise a first extension along the second direction and the connecting members of the supporting plate comprise a second extension along the second direction, and wherein the ratio between the second and first extension is smaller than 0.95.

15. The substrate carrier according to claim 12, wherein at least one of the elongate openings extends through one of the connecting members.
